(19) United States
(12) Patent Application Publication
(10) Pub. No.: US 2024/0130058 A1
(43) Pub. Date: Apr. 18, 2024

(54) PRESSURE REGULATION DEVICE

(71) Applicant: ILLINOIS TOOL WORKS INC., Glenview, IL (US)

(72) Inventors: Takashi Saeki, Glenview, IL (US); Norikaze Imazu, Glenview, IL (US); Hideki Kanie, Glenview, IL (US)

(21) Appl. No.: 18/263,887

(22) PCT Filed: Feb. 4, 2022
(86) PCT No.: PCT/US2022/015200

§ 371 Date: Aug. 1, 2023

(30) Foreign Application Priority Data
Feb. 8, 2021 (JP) 2021-018624

(51) Int. Cl. H05K 5/02; F16K 31/26; H05K 5/06

(52) U.S. Cl. CPC H05K 5/0214; F16K 31/26; H05K 5/069

(57) ABSTRACT

A pressure regulation device is attached to a waterproof case and regulates pressure within the waterproof case. The device has abase part for attachment to the waterproof case and an air conduit is joined with the base part so as to extend in the direction away from the waterproof case when the base part is attached to the waterproof case. The air conduit has first and second apertures, such that the first aperture is joined to the base part and communicates with the interior of the waterproof case and the second aperture communicates with the surrounding atmosphere. The air conduit has at least one bent part between the first and second apertures, and the second aperture is arranged between the bent part and the first end part in the height direction perpendicular to the base part.

### CROSS REFERENCE TO RELATED APPLICATIONS

This application claims the benefit of, and priority from, Japan Patent Application No. 2021-018624, filed Feb. 8, 2021, which is hereby incorporated by reference in its entirety.

### FIELD

The present invention relates to a pressure regulation device for a waterproof case.

### BACKGROUND

Electrical parts, electronics, etc., mounted on automobiles are stored in a waterproof case so that they do not come into contact with water. Since waterproof cases are sealed, they expand and contract with changes in air pressure, etc., and thus, a pressure regulation device may be required. Such pressure regulation device is a conventional pressure regulation valve or a structure in which air holes of a waterproof case are closed with a waterproof and breathable sheet material, allowing air to freely pass in and out of the waterproof case, and preventing water from entering from the outside.

### SUMMARY

### Technical Problem

In the pressure regulation devices which comprise a pressure regulation valve used in the prior art, when the positive or negative pressure in the waterproof case reaches a certain value, the valve is opened to regulate the pressure in the waterproof case. Specifically, under normal conditions, the valve is closed by a spring to prevent water from entering, and is opened only when the positive or negative pressure in the waterproof case reaches a certain value. However, it is not easy to set the spring force and to control spring manufacturing variability. Another problem with such pressure regulation devices is that they require two pressure valves, one for positive pressure and one for negative pressure.

Furthermore, a structure in which air holes are closed with a waterproof and air permeable membrane is expensive, and the waterproof case cannot be rapidly exhausted to prevent the pressure from rising when the internal pressure rises sharply. Thus, it is necessary to install an emergency pressure release valve to respond to sharp rises in the internal pressure of such a waterproof case.

In order to solve such technical problem of the prior art, an object of the present invention is to provide a pressure regulation device which regulates the pressure in a waterproof case to the surrounding atmospheric pressure while preventing water from entering the waterproof case.

### Solution to Problem

In order to achieve the object described above, according to the present invention, there is provided a pressure regulation device, which is attached to a waterproof case and which regulates pressure within the waterproof case, the device comprising a base part for attachment to the waterproof case, and an air conduit which is joined with the base part so as to extend in the direction away from the waterproof case when the base part is attached to the waterproof case, wherein the air conduit has first and second apertures, such that the first aperture is joined to the base part and communicates with the interior of the waterproof case, and so as to communicate with the surrounding atmosphere in the second aperture, the air conduit has at least one bent part between the first and second apertures, and the second aperture is arranged between the bent part and the first end part in the height direction perpendicular to the base part.

### Advantageous Effects of Invention

According to the present invention, since the second aperture of the end part on the side opposite the first end part of the air conduit joined to the base part attached to the waterproof case is arranged between the bent part and the first end part of the air conduit, the interior space of the waterproof case communicates with the surrounding atmosphere through the air conduit under normal conditions, but when the pressure regulation device is submerged in water along with the waterproof case, due to the pressure in the interior space of the waterproof case, the water is prevented from entering the second aperture, exceeding the bent part of the air conduit, and flowing into the waterproof case.

### BRIEF DESCRIPTION OF DRAWINGS

FIG. 1 is a perspective view of a pressure regulation device according to a first embodiment of the present invention, which is attached to a top wall of a waterproof case.

FIG. 2 is a cross-sectional view showing the pressure regulation device of FIG. 1 along with a waterproof case.

FIG. 3 is a perspective view of the pressure regulation device of FIG. 1 as viewed from diagonally upward.

FIG. 4 is a perspective view of the pressure regulation device of FIG. 3 as viewed from diagonally downward.

FIG. 5 is a cross-sectional perspective view of the pressure regulation device of FIG. 3.

FIG. 6 is a cross-sectional view of the pressure regulation device of FIG. 3 shown along with the top wall of the waterproof case.

FIG. 7 is a cross-sectional view similar to FIG. 6 showing the pressure regulation device submerged in water.

FIG. 8 is a cross-sectional view similar to FIG. 6 showing a modified example of a sealing member.

FIG. 9 is a perspective view of a pressure regulation device according to a second embodiment.

FIG. 10 is a cross-sectional perspective view of the pressure regulation device of FIG. 9.

FIG. 11 is a cross-sectional view of the pressure regulation device of FIG. 9 shown along with a waterproof case.

FIG. 12 is a cross-sectional view of the pressure regulation device of FIG. 9 shown along with the top wall of a waterproof case.

FIG. 13 is a cross-sectional view similar to FIG. 12 showing the pressure regulation device submerged in water.

FIG. 14 is a cross-sectional view similar to FIG. 13 showing a modified example of a float valve.

FIG. 15 is a cross-sectional view similar to FIG. 13 showing a modified example of a sealing member.

FIG. 16 is a perspective view of a pressure regulation device according to a third embodiment as viewed from diagonally upward.

FIG. 17 is a perspective view of the pressure regulation device of FIG. 16 as viewed from diagonally downward.

FIG. 18 is a perspective view of the pressure regulation device of FIG. 16 attached to the top wall as viewed from the interior of the waterproof case.

FIG. 19 is a cross-sectional view of the pressure regulation device of FIG. 16 attached to the top wall.

FIG. 20 is a cross-sectional view similar to FIG. 19 showing the pressure regulation device submerged in water.

FIG. 21 is a perspective view of a pressure regulation device according to a fourth embodiment as viewed from diagonally downward.

FIG. 22 is a cross-sectional view of the pressure regulation device of FIG. 21 attached to the top wall.

FIG. 23 is a cross-sectional view similar to FIG. 22 showing the pressure regulation device submerged in water.

FIG. 24 is a cross-sectional view of a pressure regulation device according to a fifth embodiment, shown attached to a top wall.

FIG. 25 is a cross-sectional view of the valve body used in the pressure regulation device of FIG. 24.

FIG. 26 is a cross-sectional view detailing the mode of operation when a waterproof case to which the pressure regulation device according to the fifth embodiment is attached is inclined.

FIG. 27 is a cross-sectional view detailing the mode of operation when a waterproof case to which the pressure regulation device according to the fifth embodiment is attached is inclined.

### DESCRIPTION OF EMBODIMENTS

The preferred embodiments of the present invention will be described below with reference to the attached drawings.

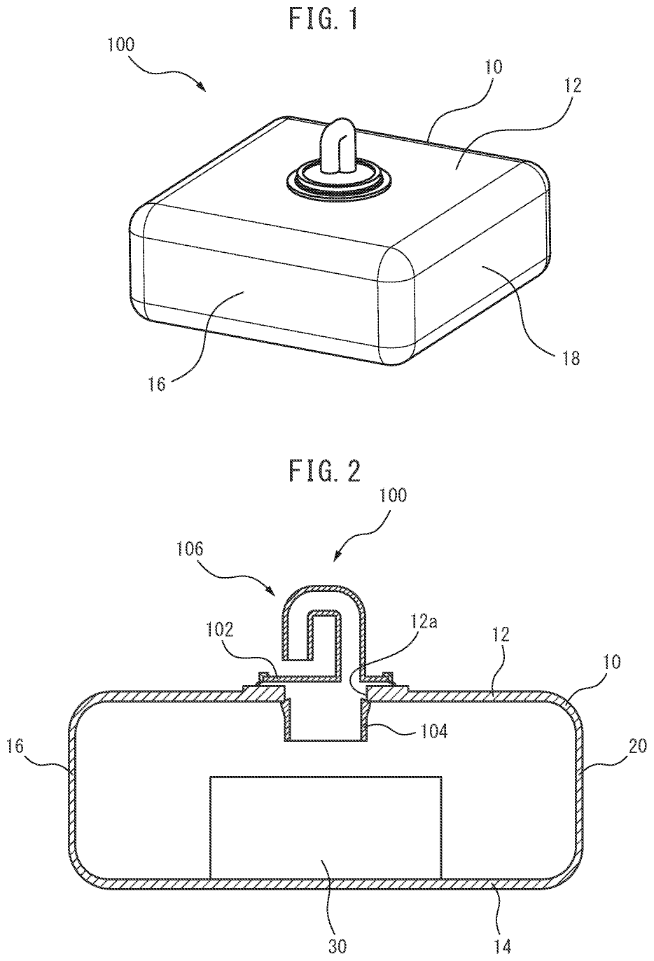

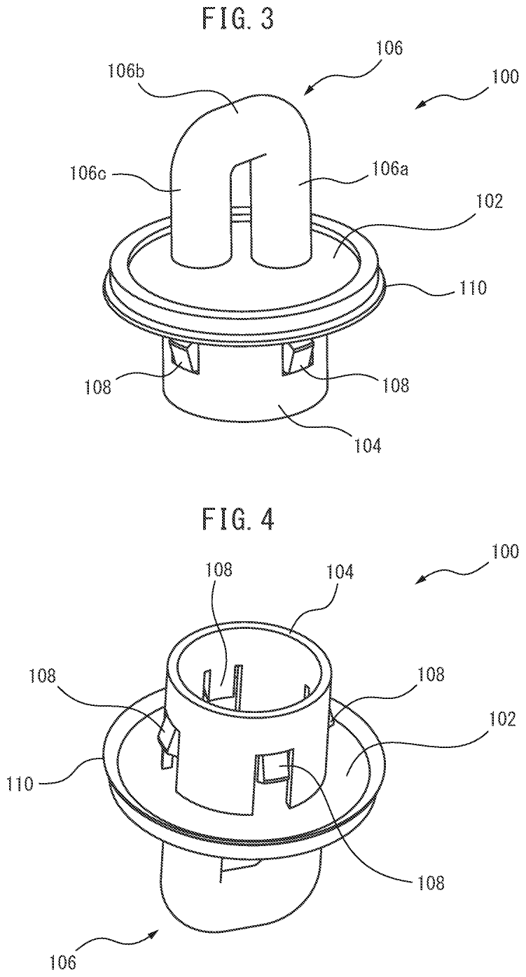

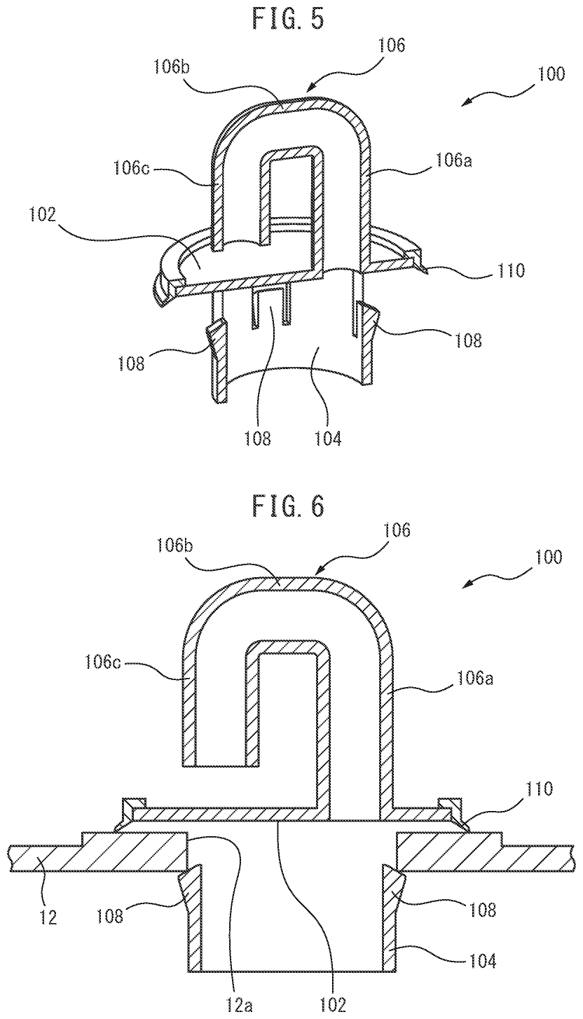

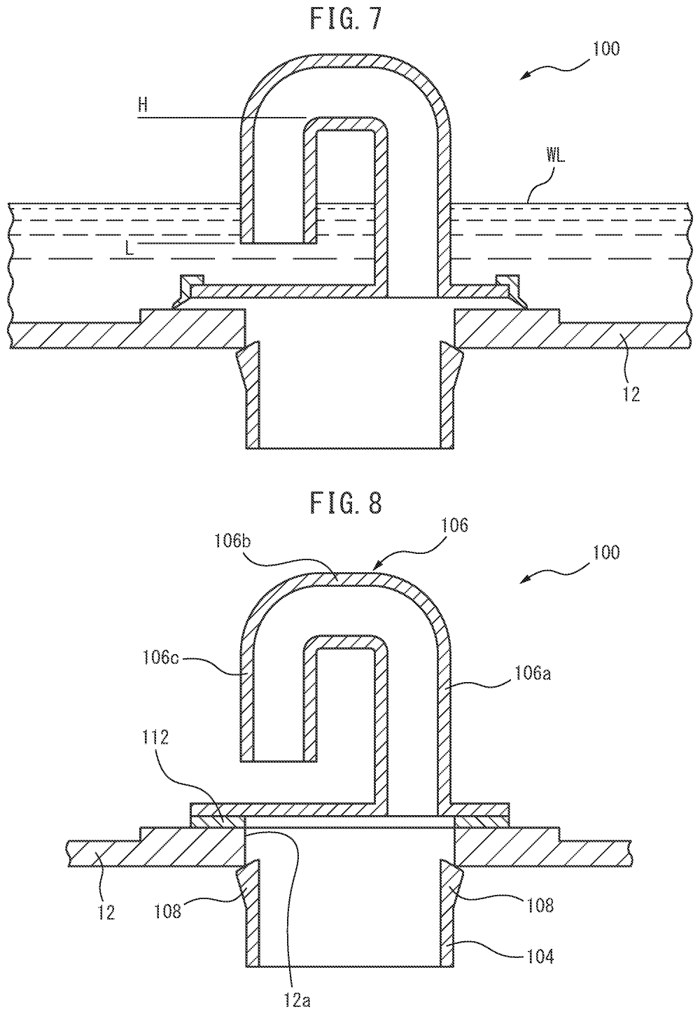

Referring to FIGS. 1 to 4, a pressure regulation device 100 according to a first embodiment of the present invention is attached to a top wall 12 of a hollow waterproof case 10. In the present example, the waterproof case 10 comprises the top wall 12 and a bottom wall 14 parallel to each other, and four side walls extending between the top wall 12 and bottom wall 14 (only side walls 16, 18, and 20 are illustrated), and is rectangular parallelepiped in shape. However, the waterproof case 10 may be any other shape. The top wall 12, the bottom wall 14, and the side walls 16 to 20 are airtightly joined to the adjacent walls. The waterproof case 10 accommodates electrical parts 30. The electrical parts 30 typically include electrical components and electronic components for the control various equipment of an automobile (not illustrated). The waterproof case 10 is arranged with the top wall 12 on the top side and the bottom wall 14 on the bottom side. In the present description, the upward-downward directions are defined with the top wall 12 on the top side.

The pressure regulation device 100 comprises, as primary constituent elements, a circular plate-shaped base part 102, a leg 104 extending from one side of the base part 102 perpendicularly to the base part 102, and an air conduit 106 protruding from the other side of the base part 102. Though the base part 102 is formed from a circular plate in the present example, it may be a polygonal plate such as quadrilateral, hexagonal, octagonal, etc.

The pressure regulation device 100 is attached to the waterproof case 10 by inserting the leg 104, which is composed of a hollow cylindrical member, into an aperture 12a formed in the top wall 12 of the waterproof case 10. The leg 104 can be a hollow columnar member having a polygonal cross-section such as a quadrilateral, hexagonal, octagonal, etc., without a cylindrical shape.

The pressure regulation device 100 preferably has a plurality, four in the present example, of locking claws 108 provided on the leg 104. The locking claws 108 protrude outwardly from the outer surface of the leg 104. When the leg 104 is inserted into the aperture 12a of the top wall 12, the locking claws 108 engage with the inner surface of the top wall 12, which prevents the pressure regulation device 100 from detaching from the top wall 12.

The pressure regulation device 100 can comprise a sealing member which prevents water from entering the waterproof case 10 from between the top wall 12 and the leg 104. In the present example, the sealing member comprises a seal lip 110 extended along the outer periphery of the base part 102. The sealing member may also be, instead of the seal lip 110, a rubber seal 112 (FIG. 8) interposed between the base part 102 and the top wall 12.

The air conduit 106 comprises a base end part or first arm part 106a extending substantially vertically from the base part 102, an intermediate part or second arm part 106b extending from the first arm part 106a substantially parallel to the base part 102, and a third arm part 106c extending from the second arm part 106b substantially parallel to the first arm part 106a, and is substantially entirely inverted U-shaped. The first arm part 106a is joined to the base part 102 so that it opens into the hollow leg 104. The first arm part 106a is also longer than the third arm part 106c. In the present embodiment, the bent part between the first and second arm parts 106a, 106b and/or the bend between the second and third arm parts 106b, 106c form the at least one bent part of the present invention.

In the present embodiment, the interior space of the waterproof case 10 communicates with the surrounding atmosphere through the leg 104 and the air conduit 106, and is always maintained at atmospheric pressure. Furthermore, even when the vehicle equipped with the waterproof case 10 and electrical parts 30 is submerged in water due to flooding, etc., since the air conduit 106 is formed in an inverted U shape, and the open end of the third arm part 106c is arranged between the bent part and the end part where the first arm part 106a is joined to the base part, when the waterproof case is sealed, the pressure in the waterproof case prevents water from entering the interior of the waterproof case 10. Specifically, as shown in FIG. 4, even if the water level WL exceeds the height L of the open end of the third arm part 106c, water cannot enter the interior of the waterproof case 10 by exceeding the second arm part 106b of the air conduit 106, which is the height of the bent part. Further, even if the water level WL exceeds the lowest point H on the inner surface of the second arm part 106b, since the pressure in the waterproof case 10 increases as the water level rises, water cannot flow into the interior of the waterproof case 10.

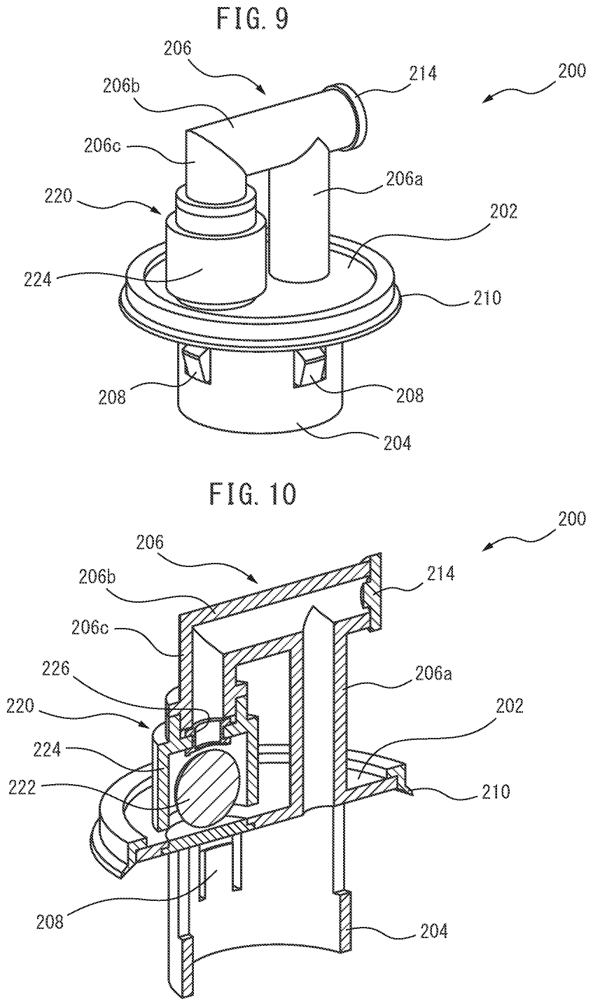

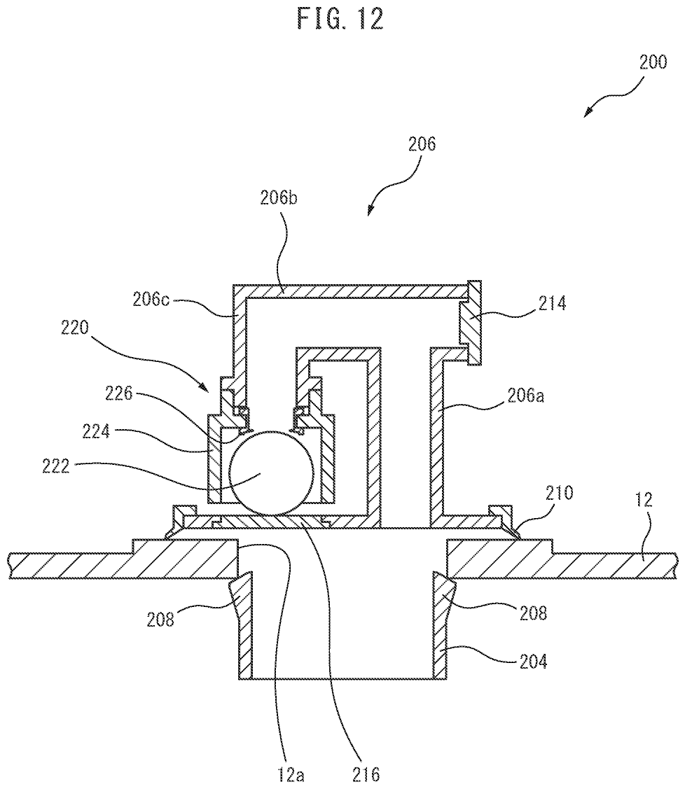

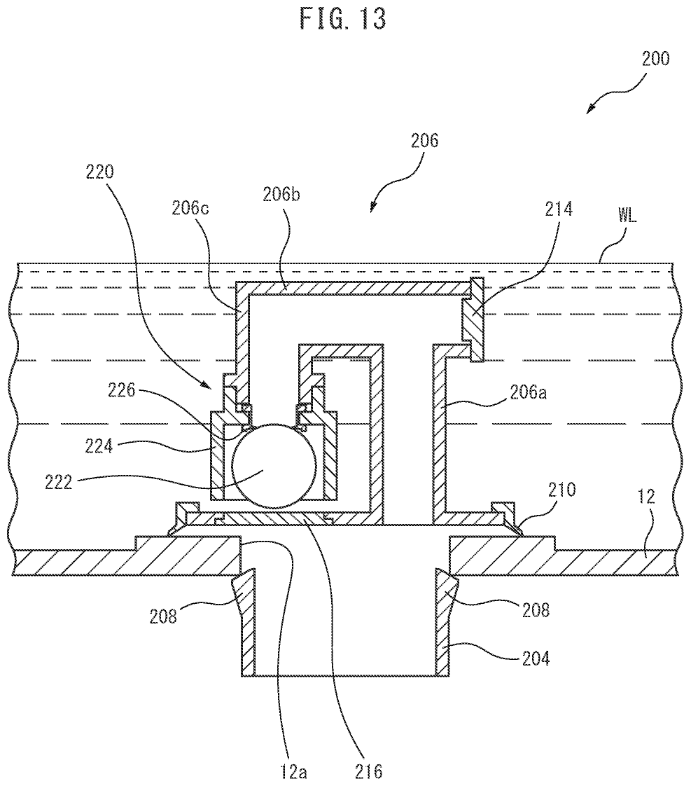

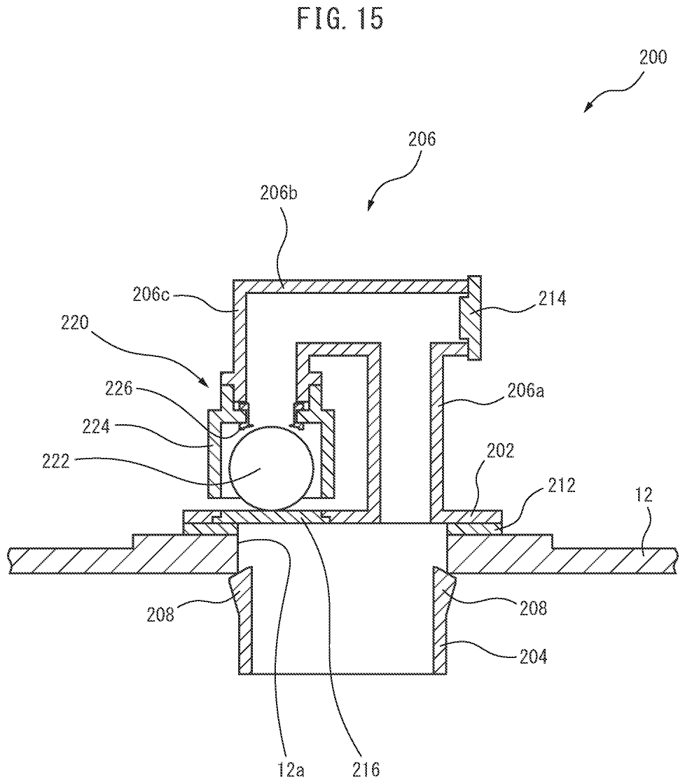

Next, a second embodiment of the present invention will be described with reference to FIGS. 8 to 15.

A pressure regulation device 200 according to a second embodiment is attached to the top wall 12 of the hollow waterproof case 10 in the same manner as the pressure regulation device 100 according to the first embodiment. The pressure regulation device 200 comprises, as primary constituent elements, a base part 202, a leg 204 extending from one side of the base part 202 perpendicular to the base part 202, and an air conduit 206 protruding from the other side of the base part 202. The base part 202 can be a circular or polygonal shaped plate in the same manner as the base part 102 of the first embodiment.

The pressure regulation device 200 is attached to the waterproof case 10 by inserting the leg 204, which is composed of a hollow cylindrical member, into the aperture 12a of the top wall 12 of the waterproof case 10. The pressure regulation device 200 preferably has a plurality, in the present example four, of locking claws 208 provided on the leg 204. The locking claws 208 protrude outwardly from the outer surface of the leg 204. When the leg 204 is inserted into the aperture 12a of the top wall 12, the locking claws 208 engage with the inner surface of the top wall 12, which prevents the pressure regulation device 200 from detaching from the top wall 12.

The pressure regulation device 200 can comprise a sealing element which prevents water from entering the waterproof case 10 from between the top wall 12 and the leg 104. In the present example, the sealing member is provided with a seal lip 210 extended along the outer periphery of the base part 202. In place of the seal lip 210, the sealing member may be a rubber seal interposed between the base part 202 and the top wall 12 in the same manner as the rubber seal 120 of the first embodiment.

The air conduit 206 comprises a base end part or first arm part 206a extending substantially vertically from the base part 202, an intermediate part or second arm part 206b extending from the first arm part 206a substantially parallel to the base part 202, and a third arm part 206c extending from the second arm part 206b substantially parallel to the first arm part 206a, and has an overall generally inverted U-shape. The first arm part 206a is joined to the base part 202 such that it opens into the hollow leg 204. The first arm part 206a is also longer than the third arm part 206c.

In the present embodiment, a float valve 220 is arranged in the outlet of the air conduit 206, that is, in the tip (the end part on the side opposite the second arm part 206b) of the third arm part 206c. The float valve 220 comprises a ball valve or a spherical valve body 222, a valve casing 224 surrounding the valve body 222, and a valve seat 226 provided at the end of the third arm part 206c of the air conduit 206. Note that as shown in FIG. 10, in the second arm part 206b, the air conduit 206 is formed so that the end part opposite the end part to which the third arm part 206c is joined is open, and by closing this opening end part with an end cap 214, the entire device 200 can be integrally molded using known molding techniques such as injection molding.

The valve body 222 can be formed from plastic or another material having a specific gravity lighter than water. The valve seat 226 is affixed to the valve casing 224 above the valve body 222. The valve seat 226 can be formed from a flexible plastic or elastomer or can be a rubber seal. The valve casing 224 is affixed to the open tip end part of the third arm part 206c. The valve casing 224 has dimensions such that a gap is formed between the lower end part of the valve casing 224 and the upper surface of the base part 202, and has an interior space that allows the valve body 222 to move mainly in the upward-downward directions. Furthermore, the base part 202 may comprise a lid 216 for placing the valve body 222 into the valve casing 224. Preferably, the lid 216 is formed from a flexible material to reduce or prevent noise generated when the valve body 222 is moved.

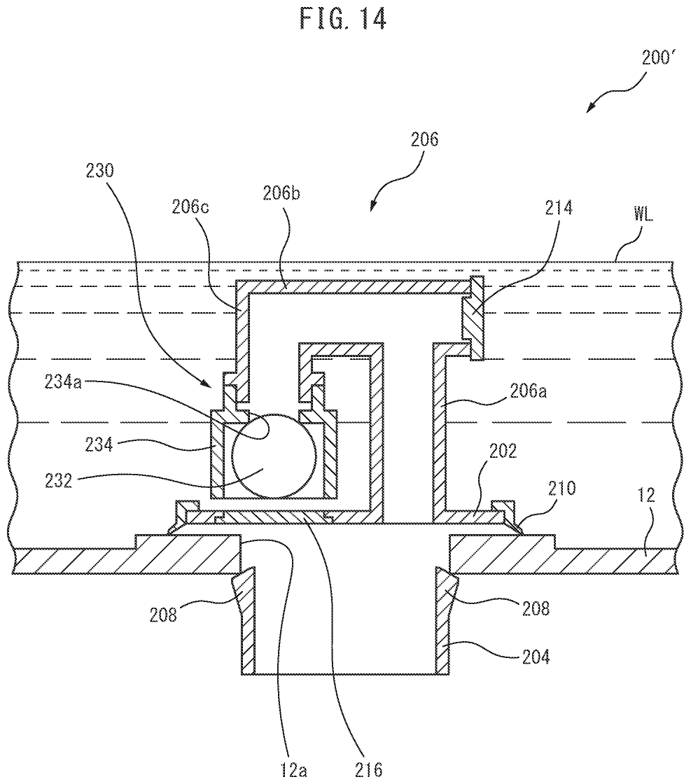

Note that by forming the valve body 222 from a flexible plastic or other material, as shown in FIG. 14, water can be prevented from flowing into the waterproof case 10 through the air conduit 206 even if the valve seat 226 is not provided. In FIG. 14, the pressure regulation device 200′ is equipped with a float valve 230 provided in the open tip end part of the third arm part 206c. The float valve 230 has a ball valve or spherical valve body 232 and a valve casing 234 surrounding the valve body 232. Since the valve 230 is made of a flexible plastic or the like, when the pressure regulation device 200′ is submerged in water, in the valve casing 234, the valve body 232 is tightly engaged with the outer peripheral portion of the aperture 234a adjacent to the opening end part of the third arm part 206c, which prevents water from entering the waterproof case 10 through the air conduit 206.

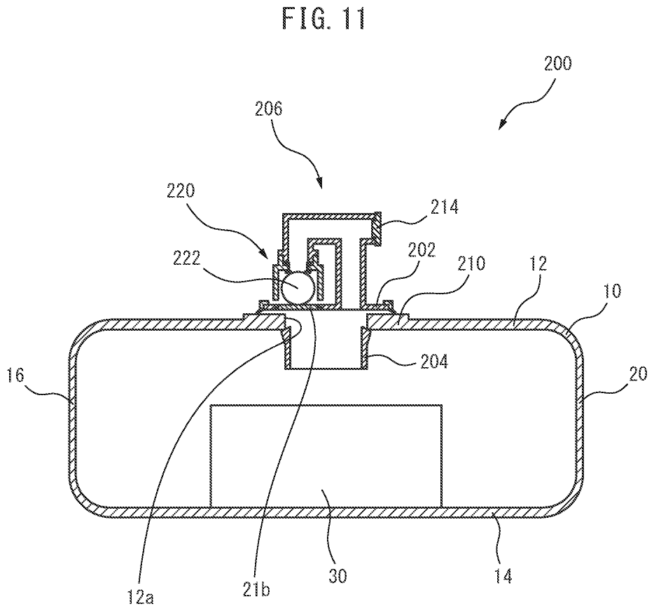

Under normal conditions, the interior space of the waterproof case 10 communicates with the ambient atmosphere via the leg 204, the air conduit 206, and the float valve 220, as shown in FIG. 8. Furthermore, as shown in FIG. 11, when a vehicle equipped with the waterproof case 10 and the electrical parts 30 is submerged in water due to flooding, etc., and the pressure regulation device 200 is also submerged in water, the valve body 222 moves upward in the valve casing 224 due to buoyancy and is pressed against the valve seat 226. As a result, the float valve 220 is closed and water is prevented from entering the waterproof case 10.

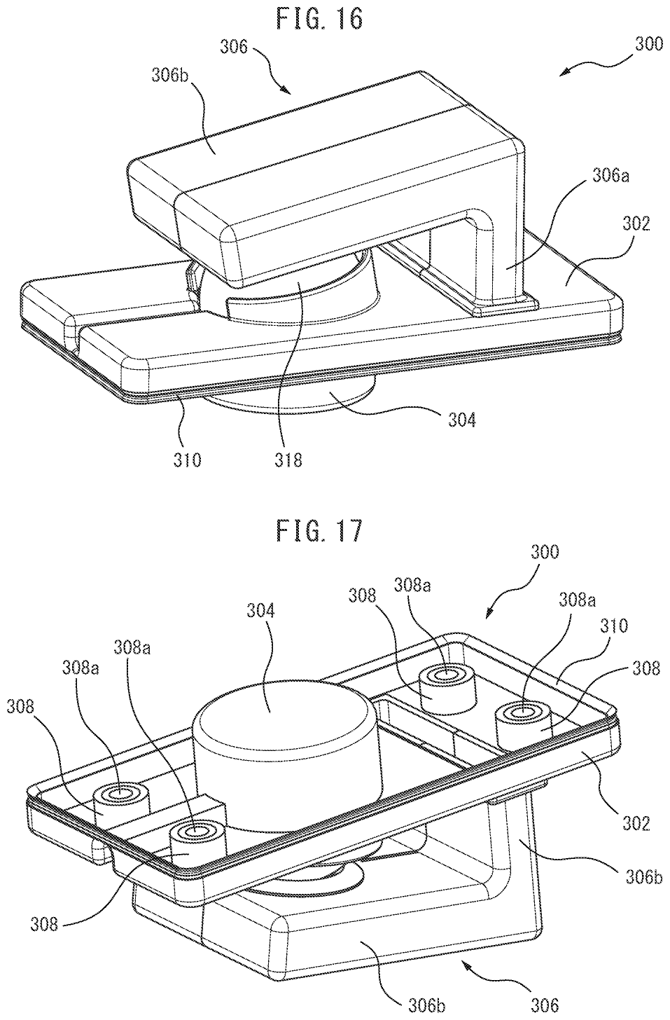

Next, a third embodiment of the present invention will be described with reference to FIGS. 16 to 20. The present embodiment is advantageous when the space above the waterproof case 10 where the pressure regulation device is installed is small, and in particular, when there is not enough space in the height direction.

The pressure regulation device 300 according to the third embodiment is a modified example of the second embodiment, and is attached to the top wall 12 of the hollow waterproof case 10 in the same manner as the pressure regulation devices 100, 200 according to the embodiments described above. The pressure regulation device 300 comprises, as primary constituent elements, a base part 302, a leg 304 protruding from one side of the base part 302, and an air conduit 306 protruding from the other side of the base part 302.

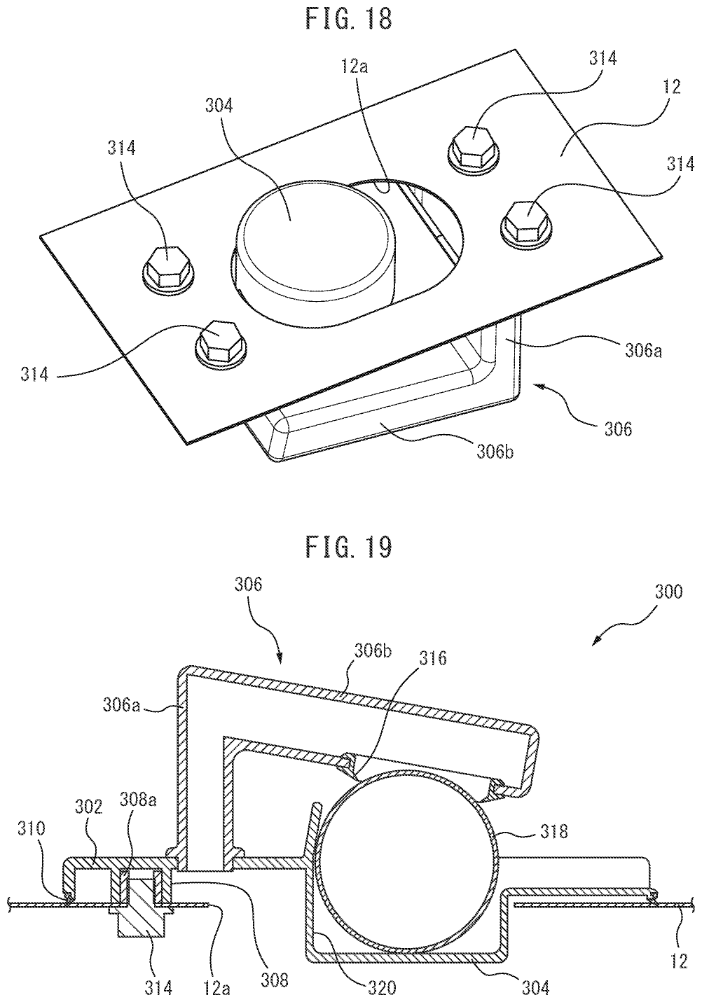

In the present embodiment, the base part 302 is formed in the shape of a rectangular plate, has a plurality of boss parts 308 on the side facing the top wall 12 when attached to the top wall 12. Internal threads 308a for receiving fasteners for affixing the base part 302 to the top wall 12, i.e., affixation screws or bolts 314 (FIG. 18) in the present embodiment, are formed in the boss parts 308. The internal threads 308a can be provided, for example, by integrally embedding nuts into which the bolts 314 are screwed when molding the base part 302 by injection molding or the like, or by embedding them in the hollow boss parts 308 after molding. The base part 302 further has a seal lip 310 as a sealing member extending along the outer peripheral portion facing the top wall 12 when attached to the top wall 12.

The air conduit 306 comprises, a base end part or first arm part 306a extending substantially vertically from the base part 302, and a second arm part 306b extending from the first arm part 306a in an inclined manner toward the base part 302, and is formed in an overall substantially L-shape. The internal angle formed by the first and second arm parts 306a, 306b is an acute angle, i.e., less than 90°. The first and second arm parts 306a, 306b form piping having a rectangular cross-section perpendicular to the flow direction of the air flowing through the interior.

In the first arm part 306a, the end part opposite the end part to which the second arm part 306b is joined mates with the aperture 302a of the base part 302. The second arm part 306b has a circular aperture formed on the side facing the base part 302, and a valve seat 316 is attached to the aperture. The valve seat 316 can be composed of a flexible plastic or elastomer or a rubber seal. In the present embodiment, the bent part between the first and second arm parts 306a, 306b forms at least one bent part of the present invention.

In the present embodiment, the leg 304 forms a valve housing. The valve housing is provided by a recess 320 facing the second arm part 306b in the base part 302. A drainage groove 322 extending from the recess 320 is formed in the base part 302. A ball valve or spherical valve body 318 is accommodated in the recess 320. The valve body 318 can be composed of plastic or the like. Alternatively, the valve body 318 can be formed hollow. The valve body 318 may be formed of foamed plastic. The air conduit 306 can be affixed to the base part 302 after the valve body 318 is arranged in the recess 320.

The pressure regulation device 300 is affixed to the top wall 12 by inserting the leg 304 into the aperture 12a formed in the top wall 12 of the waterproof case 10 and screwing the bolts 314 into the internal threads 308a of the base part 302. In the present embodiment, the aperture 12a of the top wall 12 is larger than the leg 304, and a gap is formed between it and the leg 304. In the present example, though the aperture 12a is formed as an oval or ellipse to match the shape of the base part 302, it can also be circular with a diameter greater than that of the leg 304.

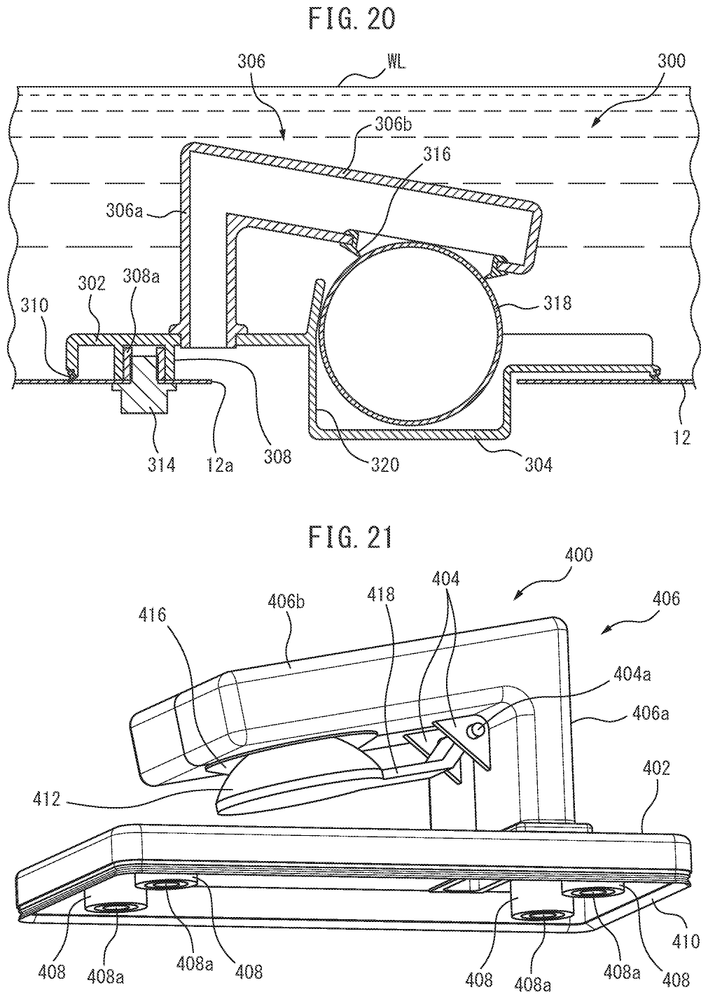

Under normal conditions, the interior space of the waterproof case 10 communicates with the surrounding atmosphere via the gap between the leg 304 and the aperture 12a, the air conduit 306, and the gap between the valve seat 316 and the valve body 318, as shown in FIG. 19, and is maintained at atmospheric pressure. Furthermore, as shown in FIG. 20, if the vehicle equipped with the waterproof case 10 and the electrical parts 30 is submerged in water due to flooding, etc., and the pressure regulation device 300 is also submerged, the valve body 318 moves upward by buoyancy and presses against the valve seat 316. Specifically, the valve body 318 and the valve seat 316 form a float valve. In this manner, in the present embodiment, when the pressure regulation device 300 is submerged in water, the float valve closes to prevent water from entering the waterproof case 10.

By inclining the second arm part 306b so that the tip thereof is downward, when the pressure regulation device 300 is submerged in water, the traveling of water through the second arm part 306b into the first arm part 306a and into the waterproof case 10 is reduced or prevented when the float valve is not yet closed, i.e., when the valve body 318 is not sufficiently pressed against the valve seat 316. Even if water should collect in the air conduit 306 when the float valve is closed, the water will be drained when the float valve is opened (the valve body 318 is downward).

Next, a fourth embodiment of the present invention will be described with reference to FIGS. 21 to 23.

The pressure regulation device 400 according to the fourth embodiment is a modified example of the third embodiment, and is attached to the top wall 12 of the hollow waterproof case 10 in the same manner as the pressure regulation devices 100, 200, and 300 according to the embodiments described above. The pressure regulation device 400 comprises, as primary constituent elements, a base part 402, an air conduit 406 protruding from the other side of the base part 402, and a valve body 412 attached to the air conduit 406 so as to rotate freely.

In the present embodiment, the base part 402 is similar to the base part 302 of the third embodiment, and is formed in the shape of a rectangular plate. The base part 402 has a plurality of boss parts 408 on the side facing the top wall 12 when attached to the top wall 12. An internal thread 408a into which there are threaded fasteners for affixation of the base part 402 to the top wall 12, i.e., affixation screws or bolts (not illustrated) in the present embodiment, is formed in the boss part 408. The internal thread 408a can be provided, for example, by integrally embedding a nut into which the fastener is screwed when molding the base part 402 by injection molding etc., or by embedding it in the hollow boss part 408 after molding. The base part 402 further has a seal lip 410 as a sealing member extending along the outer periphery facing the top wall 12 when attached to the top wall 12.

The air conduit 406 is formed in the same manner as the air conduit 306 of the third embodiment, comprises a base part or first arm part 406a extending substantially vertically from the base part 402, and a second arm part 406b extending inclined from the first arm part 406a toward the base part 402, and has an overall substantially L-shape. The first and second arm parts 406a, 406b form an acute angle therebetween. The first and second arm parts 406a, 406b form piping having a rectangular cross-section perpendicular to the direction of air flowing through the interior.

In the first arm part 406a, the end part on the side opposite the end part at which the second arm part 406b is joined mates with the aperture 402a of the base part 402. The second arm part 406b has a circular aperture on the side facing the base part 402, and a valve seat 416 is attached to the aperture. The valve seat 416 can be formed from a flexible plastic or elastomer.

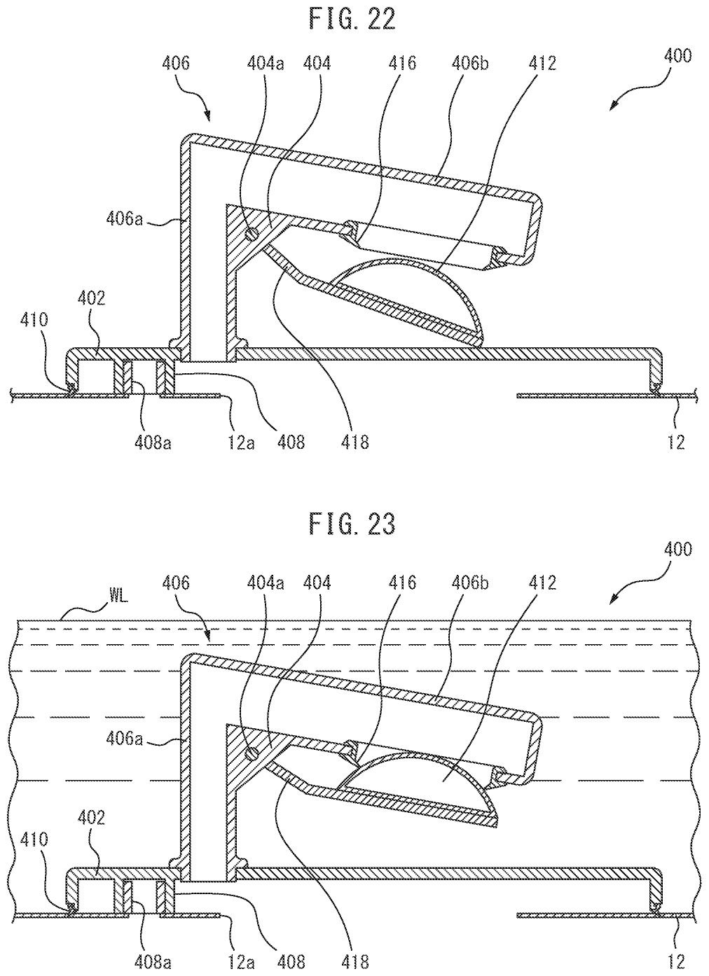

In the present embodiment, the valve body 412 is attached to the air conduit 406 so as to rotate freely. The valve body 412 is arranged so that it faces the valve seat 416 on the lower side of the second arm part 406b. The valve body 412 is joined to one end part of a lever 418. The other end part of the lever 418 is connected to the air conduit 406 so as to rotate freely. In the present embodiment, the lever 418 is connected to a bracket 404 provided between the first and second arm parts 406a, 406b by a rotation pin 404a so as to rotate freely. In this manner, the valve body 412 is attached to the air conduit 406 so as to rotate freely centered on the rotation pin 404a between the open valve position shown in FIG. 22 and the closed valve position shown in FIG. 23.

The valve body 412 has a curved surface that expands upward, and specifically, toward the valve seat 416, which can come into close contact with the ring-shaped valve seat 416. The curved surface can preferably be hemispherical or at least partially spherical. The curved surface may have a part of the surface shape of a spheroid. The valve body 412 can be formed in a hollow shape from plastic or the like. The valve body 412 may be formed of foamed plastic.

Under normal conditions, the valve body 412 is in the open valve position spaced from the valve seat 416, as shown in FIG. 22, the interior space of the waterproof case 10 communicates with the surrounding atmosphere via the aperture 12a, the air conduit 406, and the gap between the valve seat 416 and the valve body 412, and is maintained at atmospheric pressure. Furthermore, as shown in FIG. 23, when the vehicle equipped with the waterproof case 10 and electrical parts 30 is submerged in water due to flooding, etc., and the pressure regulation device 400 is also submerged in water, the valve body 412 rotates upward about the rotation pin 404a due to buoyancy and presses against the valve seat 416. Specifically, the valve body 412 and the valve seat 416 form a float valve. Thus, in the present embodiment, when the pressure regulation device 400 is submerged in water, the float valve closes to prevent water from entering the waterproof case 10.

By inclining the second arm part 406b so that the tip thereof is downward, when the pressure regulation device 400 is submerged in water, the traveling of water through the second arm part 406b into the first arm part 406a and into the waterproof case 10 is prevented or reduced when the float valve is not yet closed, specifically, when the valve body 412 is not sufficiently pressed against the valve seat 416.

Furthermore, by connecting the valve body 412 to the air conduit 406 in a rotatable manner, when the pressure regulation device 400 is submerged in water, even if the vehicle equipped with the waterproof case 10 and the electrical parts 30 are inclined, the valve body 412 does not shift from the valve seat 416 and a gap is not formed therebetween.

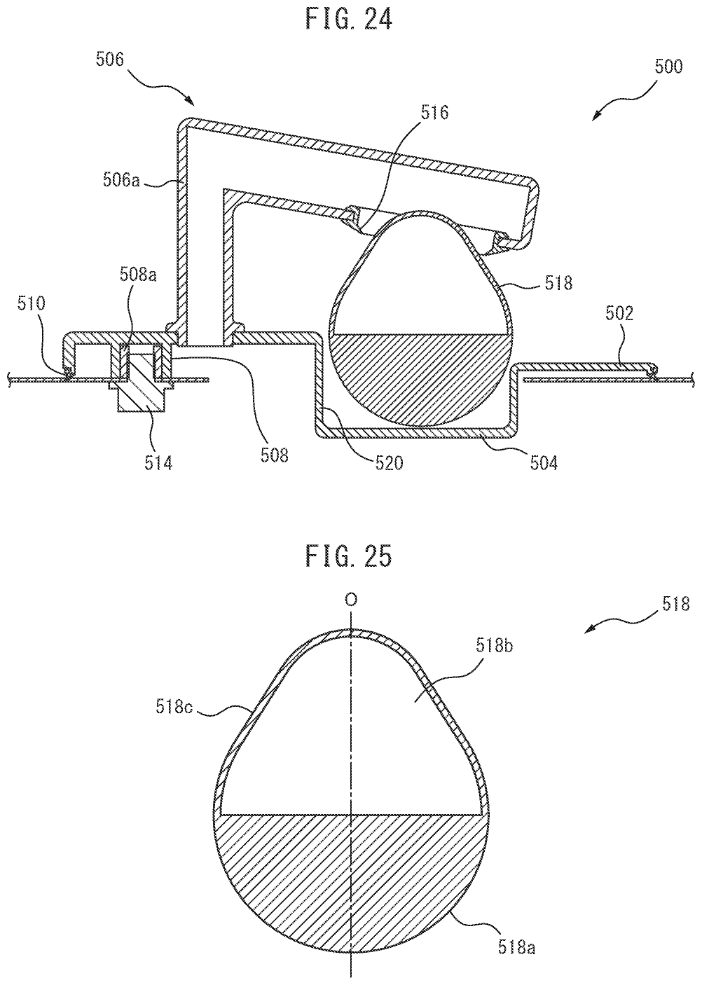

Next, a fifth embodiment of the present invention will be described with reference to FIGS. 24 to 27.

The pressure regulation device 500 according to the fifth embodiment is a modified example of the third embodiment, and is mounted on the top wall 12 of the hollow waterproof case 10 in the same manner as the pressure regulation devices 100, 200 and 300 according to the embodiments described above. The pressure regulation device 500 comprises, as primary constituent elements, a base part 502, a leg 504 protruding from one side of the base part 502, and an air conduit 506 protruding from the other side of the base part 502.

In the present embodiment, the base part 502 is formed in the shape of a rectangular plate, and has a plurality of boss parts 508 on the side facing the top wall 12 when attached to the top wall 12. Internal threads 508a into which there are threaded fasteners for attaching the base part 502 to the top wall 12, i.e., affixation screws or bolts 514 in the present embodiment, are formed in the boss parts 508. The internal threads 508a can be provided, for example, by integrally embedding nuts into which the bolts 514 are screwed when molding the base part 502 by injection molding or the like, or by embedding them in the hollow boss parts 508 after molding. The base part 502 further has a seal lip 510 as a sealing member extending along the outer periphery facing the top wall 12 when attached to the top wall 12.

The air conduit 506 comprises a base end part or first arm part 506a extending substantially vertically from the base part 502 and a second arm part 506b extending obliquely from the first arm part 506a toward the base part 502, and is overall substantially L-shaped. The interior angle formed by the first and second arm parts 506a, 506b is acute, i.e., less than 90°. The first and second arm parts 506a, 506b form piping having a rectangular cross-section perpendicular to the flow direction of air circulating through the interior.

In the first arm part 506a, the end part on the side opposite the end part to which the second arm part 506b is joined mates with the aperture 502a of the base part 502. The second arm part 506b has a circular aperture on the side facing the base part 502, and a valve seat 516 is attached to the aperture. The valve seat 516 can be formed from a flexible plastic or elastomer or a rubber seal.

In the present embodiment, the leg 504 forms a valve housing. The valve housing is provided by a recess 520 facing the second arm part 506b in the base part 502. The base part 502 may have a drainage groove 322 extending from the recess 520. An oval shaped valve body 518 is accommodated in the recess 520. The air conduit 506 can be affixed to the base part 502 after the valve body 518 is arranged in the recess 520.

The pressure regulation device 500, as described below, has a structure which is substantially identical to the pressure regulation device 300 according to the third embodiment, except that the spherical valve body 412 of the third embodiment is replaced with an egg-shaped valve body 518.

The valve body 518 comprises a bottom part or large diameter part 518a, a top part or small diameter part 518b, and a transition part 518c formed between large diameter part 518a and the small diameter part 518b. The large diameter part 518a and the small diameter part 518b have at least a partially spherical or spheroidal surface shape. The large diameter part 518a has a greater diameter than the small diameter part 518b. As a whole, the valve body 518 has a rotationally symmetric shape with respect to the central axis O connecting the centers of the large diameter part 518a and the small diameter part 518b.

The valve body 518 can be formed from plastic or the like. The valve body 518 may be formed of foamed plastic. As shown in FIG. 25, the large diameter part 518a of the valve body 518 is solid while the small diameter part 518b and the transition part 518c are hollow. In this manner, the center of gravity of the valve body 518 is near the center of the large diameter part 518a. Thus, when the valve body 518 is arranged on a plane (not illustrated), the small diameter part 518b is stable in a state of being arranged on the upper side of the large diameter part 518a. At this time, the central axis O becomes parallel to the direction of gravity. However, when a force acts on the small diameter part 518b in the lateral direction, for example, in the direction perpendicular to the central axis O, the central axis O easily swings around the center of gravity. Specifically, when a force having a directional component in the lateral direction or perpendicular to the central axis O acts on the small diameter part 518b, even if the force is small, the small diameter part 518b is easily displaced in the direction of the force (the direction perpendicular to the central axis O). If the large diameter part 518a is heavier than the small diameter part 518b and the small diameter part 518b is automatically arranged on the upper side of the large diameter part 518a and is stable, the small diameter part 518b does not have to be formed in a hollow shape.

Under normal conditions, as shown in FIG. 24, the interior space of the waterproof case 10 communicates with the surrounding atmosphere via the gap between the leg 504 and the aperture 12a, the air conduit 506, and the gap between the valve seat 516 and the valve body 518, and is maintained at atmospheric pressure. When the vehicle equipped with the waterproof case 10 and the electrical parts 30 is submerged due to flooding, etc., and the pressure regulation device 500 is also submerged in the water, the valve body 518 moves upward due to buoyancy and is pressed against the valve seat 516. Specifically, the valve body 518 and the valve seat 516 form a float valve. As described above, in the present embodiment, when the pressure regulation device 500 is submerged in water, the float valve closes and the entry of water into the waterproof case 10 is prevented.

Furthermore, by inclining the second arm part 506b so that the tip is downward, when the pressure regulation device 500 is submerged in water, the float valve is not yet closed, that is, when the valve body 518 is not sufficiently pressed against the valve seat 516, the traveling of water through the second arm part 506b into the first arm part 506a and into the waterproof case 10 is reduced or prevented.

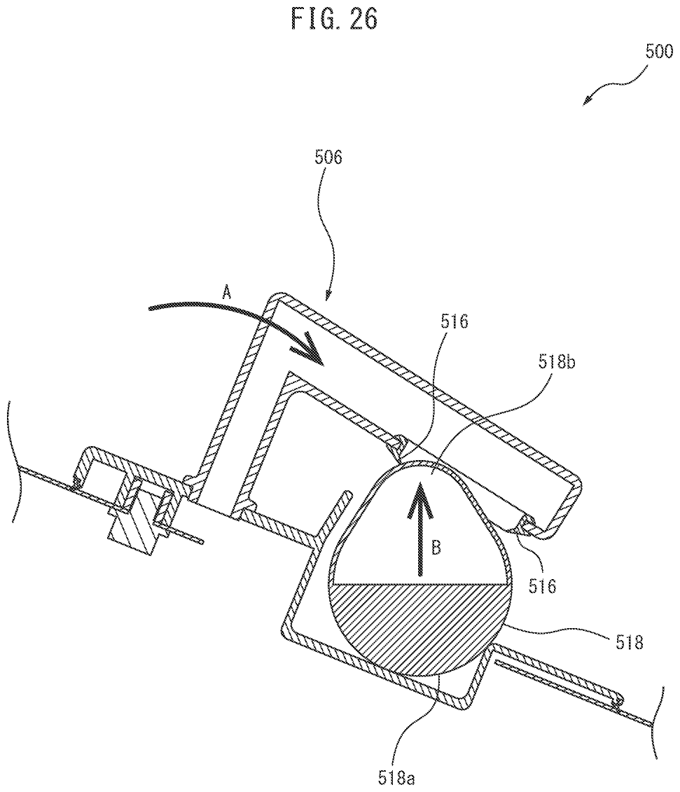

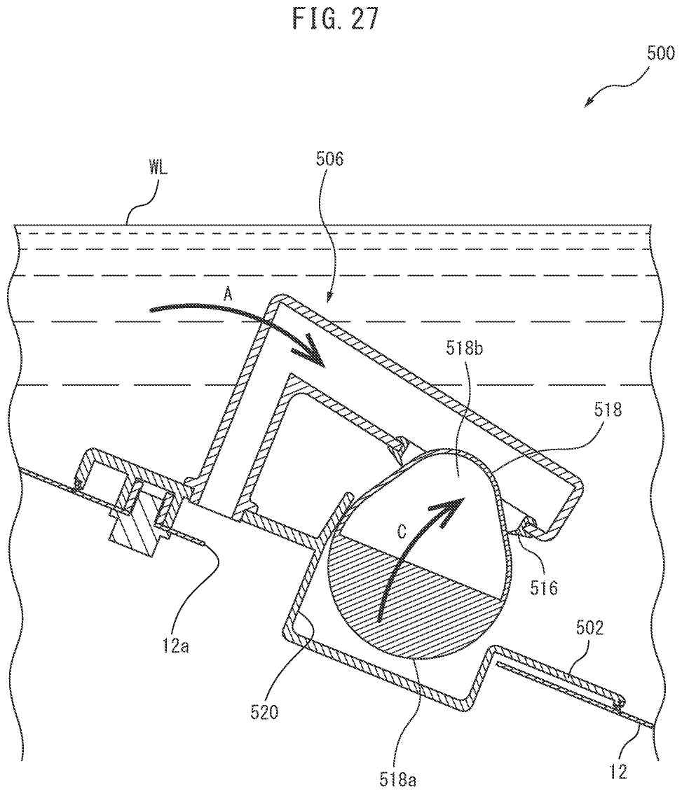

Further, by forming the valve body 512 into an egg shape and making the large diameter part 518a heavier than the small diameter part 518b, when the pressure regulation device 500 is submerged in water, if the vehicle equipped with the waterproof case 10 and the electrical parts 30 is tilted as indicated by arrow A in FIG. 26, the small diameter part 518b of the valve body 518 that has moved upward as indicated by arrow B due to buoyancy comes into contact with a part of the valve seat 516, and in FIG. 26, an edge portion 516a located on the upper side due to the inclination of the vehicle. As a result, as indicated by arrow C in FIG. 27, the valve body 518 swings easily, the small diameter part 518b and/or the transition part 518c fits snugly into the valve seat 516, and the float valve closes.

### REFERENCE SIGNS LIST

10 waterproof case
12 top wall
12a aperture
14 bottom wall
16 side wall
18 side wall
20 side wall
30 electrical part
100 pressure regulation device
102 base part
104 leg
106 air conduit
106a first arm part
106b second arm part
106c third arm part
108 locking claw
110 seal lip
120 rubber seal
200 pressure regulation device
202 base part
202a lid
204 leg
206 air conduit
206a first arm part
206b second arm part
206c third arm part
208 locking claw
210 seal lip
214 end cap
220 float valve
222 valve body
224 valve casing
226 valve seat
300 pressure regulation device
302 base part
302a aperture
304 leg
306 air conduit
306a first arm part
306b second arm part
308 boss part
308a internal thread
310 seal lip
314 bolt
316 valve seat
318 valve body
320 recess
322 drainage groove
400 pressure regulation device
402 base part
402a aperture
404 bracket
404a rotation pin
406 air conduit
406a first arm part
406b second arm part
408 boss part
408a internal thread
410 seal lip
412 valve body
416 valve seat
418 lever
500 pressure regulation device
502 base part
502a aperture
504 leg
506 air conduit
506a first arm part
506b second arm part
508 boss part
508a internal thread
510 seal lip
512 valve body
514 bolt
516 valve seat
516a edge portion
518 valve body
518a large diameter part
518b small diameter part
518c transition part
520 recess

1. A pressure regulation device, which is attached to a waterproof case and which regulates pressure within the waterproof case, the device comprising:
a base part for attachment to the waterproof case, and
an air conduit which is joined with the base part so as to extend in the direction away from the waterproof case when the base part is attached to the waterproof case, wherein
the air conduit has first and second apertures, such that the first aperture is joined to the base part and communicates with the interior of the waterproof case, and so as to communicate with the surrounding atmosphere in the second aperture,
the air conduit has at least one bent part between the first and second apertures, and the second aperture is arranged between the bent part and the first end part in the height direction perpendicular to the base part.

2. The pressure regulation device according to claim 1, wherein the air conduit comprises a first arm part having the first aperture on one end thereof, a second arm part joined to an end part of the first arm part on the side opposite the first aperture, and a third arm part joined to an end part of the second arm part on the side opposite the end part to which the first arm part is joined,
the third arm part comprises the second aperture in an end part on the side opposite the end part to which the second arm part is joined, and
the first arm part and the third arm part extend substantially perpendicular to the base part, and the second end part is arranged above the base part.

3. The pressure regulation device according to claim 2, wherein a float valve is disposed in the second end part.

4. The pressure regulation device according to claim 4, wherein the float valve comprises a valve casing which is attached to the second end part, and a valve body which is provided within the valve casing so as to be movable between the second end part and the base part,
the valve casing is formed in a hollow tubular shape having first and second opening end parts, the first opening end part is joined to the second end part of the air conduit, and the second opening end part faces the base part and is spaced from the base part.

5. The pressure regulation device according to claim 1, wherein the air conduit has a first arm part having the first aperture on one end thereof and a second arm part joined to an end part of the first arm part on the side opposite the first aperture and is formed in an L-shape as a whole,
the second aperture is formed in the second arm part on a side surface facing the base part, and
the air conduit comprises a float valve having a valve body which closes the second aperture by buoyancy.

6. The pressure regulation device according to claim 5, further comprising a recess which is formed in the base part, and which accommodates the valve body of the float valve so as to be capable of mating with and separating from the second aperture.

7. The pressure regulation device according to claim 6, wherein the valve body of the float valve is a hollow sphere.

8. The pressure regulation device according to claim 6, wherein the valve body of the float valve comprises a large diameter part having an at least partially spherical surface, and a small diameter part having an at least partially spherical surface, and the large diameter part has a diameter greater than that of the small diameter part, and
the small diameter part is hollow and the large diameter part is at least partially solid.

9. The pressure regulation device according to claim 5, further comprising a lever which is connected to the air conduit so as to enable the valve body of the float valve to mate with and separate from the second aperture.

10. The pressure regulation device according to claim 9, wherein the valve body of the float valve comprises a hollow member having a spherical surface which closely engages with an edge of the second aperture.

11. The pressure regulation device according to claim 5, wherein the first and second arm parts are piping having a rectangular cross-section.

12. The pressure regulation device according to claim 5, wherein the first and second arm parts form an acute angle therebetween.

13. The pressure regulation device according to claim 5, wherein the valve body of the float valve comprises a hollow member having a spherical surface which closely engages with an edge of the second aperture.
